(19) United States
(12) Patent Application Publication
(10) Pub. No.: US 2007/0026671 A1
(43) Pub. Date: Feb. 1, 2007

(54) Method of forming low resistance tungsten films

(75) Inventors: Rak-Hwan Kim, Suwon-si (KR); Young-Cheon Kim, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/476,793

(22) Filed: Jun. 29, 2006

(30) Foreign Application Priority Data
Jul. 13, 2005 (KR) 2005-63063

(51) Int. Cl. H01L 21/4763; H01L 21/44

(52) U.S. Cl. 438/648; 438/642; 438/685

(57) ABSTRACT

Provided is a method for forming low resistance metal films in which an underlying film, for example, a barrier layer or an adhesion layer, is formed on a semiconductor substrate. The underlying film is then subjected to a partial etch back in order to reduce the surface roughness and form a deposition surface. A metal film, for example, a tungsten film, is then formed on a deposition surface that has been formed on the underlying film. Forming the metal film on the deposition surface that has reduced surface roughness will tend to produce a metal film having a larger average grain size and, consequently, a lower sheet resistivity for a given film thickness.

### PRIORITY STATEMENT

This application claims priority under 35 USC § 119 from Korean Patent Application No. 2005-63063, which was filed on Jul. 13, 2005, the contents of which are herein incorporated by reference in its entirety.

### BACKGROUND OF THE INVENTION

1. Field of the Invention

The invention relates to a method of manufacturing a semiconductor device, and more particularly, relates to a method of forming a tungsten film having a low resistance.

2. Description of the Related Art

The trend toward increasing the integration density and/or improving the performance of semiconductor devices has led to lower operating voltages and reduced critical feature sizes for the patterns and structures formed on such chips has necessitated various adjustments to the materials and techniques used to form these increasingly more demanding patterns. While polysilicon has been a widely used conductive material for fabricating interconnecting wiring, for example, gate electrodes and/or bit lines, as the pattern sizing continues to decrease the resistance of the resulting polysilicon structures also tends to increase. These resistance increases will tend to result in both increasing RC time delays and 1R voltage drops. Accordingly, lower resistance interconnecting materials, for example, a metal or metal alloy, are being more widely used for interconnecting wiring.

Aluminum (Al) and aluminum alloys are the most common interconnecting materials used in very large scale integrated (VLSI) circuits. However, the aluminum is not suitable for use in self-aligned MOS processes that will require subsequent high temperature processing due to low melting point of the aluminum. Therefore, low resistance refractory metals such as tungsten (W), titanium (Ti), molybdenum (Mo) and tantalum (Ta) and silicides prepared from the refractory metals have been adopted for forming initial interconnecting wiring, for example, gate electrodes and/or bit lines found in VLSI semiconductor devices.

Of the refractory metals, tungsten has been found to offer a desirable combination of properties for use as an interconnecting material including, for example, relatively low resistivity, relatively low stress of about 5×10⁹ dyn/cm³, good conformal step coverage and a thermal expansion coefficient equivalent to that of silicon. Further, tungsten can be used to form a low resistance contact to the silicon because the tungsten has good electromigration resistance, thereby causing no stoichiometry control.

FIGS. 1A to 1C are cross-sectional views illustrating a method of forming a tungsten wiring in a semiconductor device according to a conventional method. As illustrated in FIG. 1A, after forming transistors (not shown) having gate electrodes and source/drain regions on a semiconductor substrate 10, silicon oxide is deposited on the transistors and the substrate 10 to form an insulating layer 12. A photoresist pattern is then formed on the insulating layer 12 and the insulating layer 12 is then partially removed using the photoresist pattern as an etch mask to form an insulating pattern including first contact holes 14. The first contact holes 14 expose portions of the gate electrodes and the source/drain regions of the transistors.

A doped polysilicon film is deposited on the insulating layer 12 to a thickness sufficient to fill the first contact holes 14. An upper portion of the doped polysilicon film is then removed by a chemical mechanical polishing (CMP) process or an etch-back process to expose the upper surface of the insulating layer 12 and form a planarized surface suitable for subsequent processing. The portions of the doped polysilicon film remaining in the first contact holes 14 form self-aligned contact (hereinafter referred to as SAC) pads 16 or conductive plugs through which electrical contact may be established to the gate electrodes (not shown) and source/drain regions.

A layer of silicon oxide is then deposited on the SAC pads 16 and the insulating layer 12 to form an insulating interlayer 18. A photoresist pattern (not shown) is then formed on the insulating interlayer 18, after which the exposed portions of the insulating interlayer 18 are etched to form a second contact hole 20 through which a portion of the surface of the SAC pad 16 is exposed.

A titanium film 22 and a titanium nitride (TiN) film 24 are sequentially deposited on the second contact hole 20 and the insulating interlayer 18 to form a barrier layer 25. Then, a tungsten film 26 is deposited on the barrier layer 25 to a thickness sufficient to fill the remaining portion of the second contact hole 20.

As illustrated in FIG. 1B, an upper portion of the tungsten film 26 is then removed by a CMP process or an etch-back process to expose the upper surface of the insulating interlayer 18 and form a planarized surface, thereby forming a tungsten contact plug 26a in the second contact hole 20. Thereafter, titanium nitride is deposited on the insulating interlayer 18 and the surface of tungsten contact plug 26a to form an adhesion layer 28.

As illustrated in FIG. 1C, a tungsten film is then formed on the adhesion layer 28, after which the tungsten film is patterned and etched to form a tungsten pattern that includes a bit line 30 that is electrically connected to the SAC pad 16 through the tungsten contact plug 26a As described above, tungsten wiring has attracted attention for use as an interconnecting electrode, for example, the gate electrodes and/or the bit lines utilized in connecting the various components of a VLSI semiconductor device. However, as the design rules for the fabrication of semiconductor devices continue gradually decreasing, the linewidth of the tungsten wiring will also be reduced, raising the resistance of the tungsten interconnection wiring to a degree whereby the operating speed of the final devices may be degraded.

Although the sheet resistance (Rₛ) of the tungsten film may be decreased by increasing the thickness of the film and/or increasing the width of the tungsten interconnection wiring, the increased thickness of the layer and/or the decreased space between adjacent tungsten lines will both tend to increase the difficulty associated with patterning and etching the tungsten wiring successfully, e.g., exhibiting good dimensional control and without forming opens or shorts in the metal pattern. Therefore, the resistance of the tungsten film should be reduced in order to allow for decreasing the linewidth of the tungsten pattern and/or the thickness of the tungsten layer.

In general, tungsten films are formed whereby nuclei creation and grain growth are accomplished with the surface state of the underlying film. In those cases where the surface of the underlying film is uniformly rough, the tungsten nuclei forming on such films tend to exhibit improved uniformity, relatively smaller size and grain growth corresponding to the shape defined by the created nuclei. Accordingly, the resulting tungsten films will also tend to exhibit a grain structure having a relatively uniform size distribution and a relatively small average grain size. Conversely, when the surface of the underlying film is smooth, the tungsten nuclei formed on the surface are generally larger and the grains growing from each of the nuclei will also tend to be larger. Accordingly, the resulting tungsten films will also tend to exhibit a grain structure having a wider size distribution and a larger average grain size than tungsten films formed on a uniformly rough surface.

As noted above, the average grain size and size distribution of a tungsten film varies with the condition or surface state of the surface of the underlying film on which the tungsten layer is formed. It is also known that the sheet resistance of the tungsten film varies with the grain size of the tungsten film with larger grains tending to decrease the resistance of the resulting tungsten film.

### SUMMARY OF THE INVENTION

Example embodiments of the invention include methods of forming a low resistance tungsten film, methods of forming tungsten wiring capable of reducing resistance in a semiconductor device and methods of fabricating semiconductor devices incorporating such tungsten films and tungsten wiring.

A method according to an example embodiment of the invention, forms a low resistance tungsten film by forming an underlying film on a semiconductor substrate, subjecting the underlying film to a partial etchback process to reduce surface roughness of the underlying film and form a smooth surface, and forming a tungsten film on the smooth surface of the underlying film.

Example embodiments of the invention include, for example, incorporating a partial etchback process that produces a smooth surface on the underlying film that exhibits a RMS (root-mean-square) roughness of no more than about 1 nm, i.e., no more than about 10 Å.

Example embodiments of the invention also include a method of forming tungsten wiring in a semiconductor device in which an insulating interlayer is formed on a semiconductor substrate. Portions of the insulating interlayer are removed to form a contact hole pattern that exposes portions of the semiconductor substrate, for example, portions of the gate electrodes and/or source/drain regions underlying the insulating interlayer. A tungsten contact plug is formed in the contact hole. An adhesion layer is formed on the surface of the insulating interlayer and the surface of the tungsten contact plug. The adhesion layer is subjected to a partial etch to reduce the roughness and form a smooth surface. A tungsten layer is formed on the smooth surface of the adhesion layer, and the tungsten layer and the adhesion layer are patterned and etched to form a tungsten wiring pattern on the adhesion layer. In some embodiments of the invention, the adhesion layer may include titanium nitride.

Example embodiments of methods according to the invention include forming the tungsten contact plug in the contact hole with a barrier layer interposed therebetween the insulating material and the tungsten. This structure may be achieved by forming the barrier layer on the contact hole and the insulating interlayer, forming a tungsten film on the barrier layer to fill the remaining portion of the contact hole and then removing upper portions of the tungsten film and the barrier layer to expose an upper surface of the insulating interlayer.

Example embodiments of the invention also include methods of forming tungsten wiring in a semiconductor device. These methods may include forming an insulating interlayer on a semiconductor substrate, then patterning and etching the insulating interlayer to form a contact hole that exposes a portion of the semiconductor substrate. A barrier layer may then be formed on the surfaces defining the contact hole and the upper surface of the insulating interlayer.

This barrier layer may then be subjected to a partial etchback process that will reduce the surface roughness and increase the smoothness of the etched surface of the barrier layer. A tungsten film is then formed on the etched surface of the barrier layer, whereby the decreased roughness will tend to produce a larger grain structure and reduced resistance in the tungsten film. The tungsten film and the barrier layer may then be patterned and etched to form a tungsten wiring pattern.

Example embodiments of the invention may also include a stacked barrier layer structure having that may include, for example, a titanium film formed on the surfaces of the contact hole and the surface of the insulating interlayer and a titanium nitride film formed on the titanium film.

Example embodiments of the invention include methods in which the partial etch back of the barrier layer, for example, a titanium nitride film or a titanium film, is left with a RMS surface roughness of no more than about 10 Å. Example embodiments of the invention also include methods in which the partial etch process is of sufficiently short duration whereby an adequate thickness of the barrier layer remains to serve as the barrier layer.

According to example embodiments of the invention, the surface roughness of the underlying layer, for example, an adhesion layer or a barrier layer, is reduced by the etch back process before the primary conductive layer, for example, a tungsten film, is deposited on the underlying layer. Because the primary conductive layer is deposited on the smoothed surface of the underlying film, the conductive layer exhibits increased grain size and, consequently, reduced sheet resistance.

### BRIEF DESCRIPTION OF THE DRAWINGS

The invention will become more apparent by consideration of the written description below in which example embodiments are detailed with reference to the attached drawings in which:

FIGS. 1A to 1C are cross-sectional views illustrating a method of forming a tungsten wiring in a semiconductor device according to a conventional method;

FIGS. 2A to 2E are cross-sectional views illustrating a method of forming a tungsten wiring in a semiconductor device according to a first example embodiment of the invention;

FIGS. 3A to 3C are cross-sectional views illustrating a method of forming a tungsten wiring pattern on a semiconductor device according to a second example embodiment of the invention;

FIGS. 4A and 4B are cross-sectional views schematically illustrating the surface morphology of a titanium nitride film and a tungsten film formed according to a conventional method and by a method according to an example embodiment of the invention, respectively; and

FIGS. 5A and 5B are pictures showing the surfaces of the titanium nitride film and tungsten film photographed by scanning electron microscope (SEM) according to a convention method and by a method according to an example embodiment of the invention, respectively.

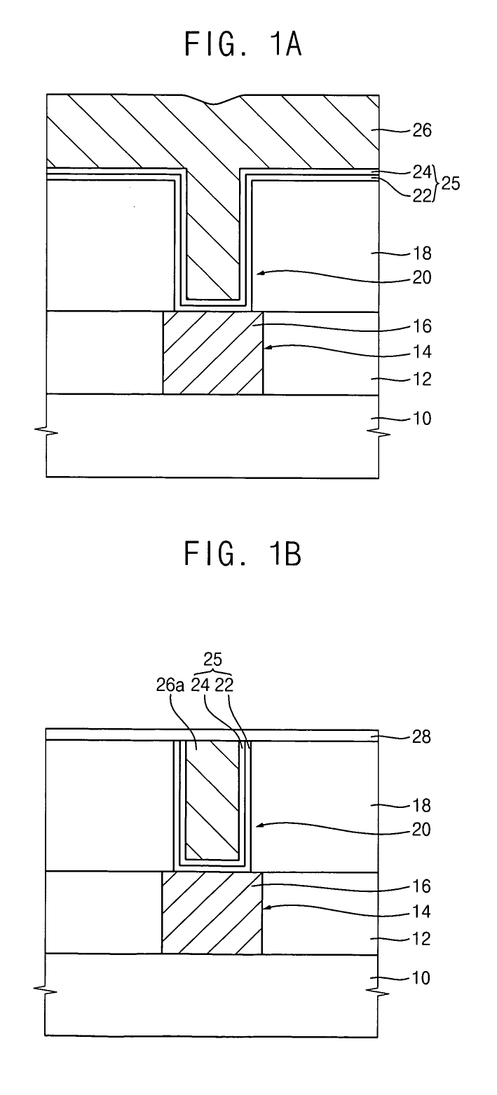

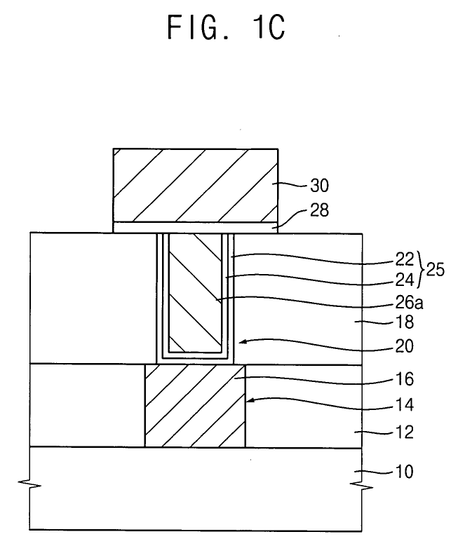

These drawings are provided for illustrative purposes only and are not drawn to scale. The spatial relationships and relative sizing of the elements illustrated in the various embodiments, for example, the various films comprising the memory device and/or gate structures, may have been reduced, expanded or rearranged to improve the clarity of the figure with respect to the corresponding description. The figures, therefore, should not be interpreted as accurately reflecting the relative sizing, value or positioning of the corresponding structural elements that could be encompassed by actual nonvolatile memory devices manufactured according to the example embodiments of the invention.

### DESCRIPTION OF EXAMPLE EMBODIMENTS

The invention now will be described more filly hereinafter with reference to the accompanying drawings, in which embodiments of the invention are shown and in which identical reference numbers identify identical or corresponding elements in the various drawings. This invention may, however, be embodied in many different forms and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present. In contrast, when an element is referred to as being “directly on” another element, there are no intervening elements present. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first thin film could be termed a second thin film, and, similarly, a second thin film could be termed a first thin film without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and should not, therefore, be interpreted in an idealized or overly formal sense unless expressly so defined herein.

Embodiments of the invention are described herein with reference to cross section illustrations that are schematic illustrations of idealized embodiments of the invention. As such, variations from the shapes of the illustrations as a result, for example, of manufacturing techniques and/or tolerances, are to be expected. Thus, embodiments of the invention should not be construed as limited to the particular shapes of regions illustrated herein but should be considered as including deviations in shapes that result, for example, from the particular manufacturing processes employed in practicing the invention. For example, a region illustrated or described as flat will, typically, exhibit some degree of surface roughness, non-uniformity and/or nonlinear features. Moreover, sharp angles that are illustrated may be rounded. Thus, the regions illustrated in the figures are schematic in nature and their shapes are not intended to illustrate the precise shape of a region and are not intended to limit the scope of the invention.

### First Example Embodiment

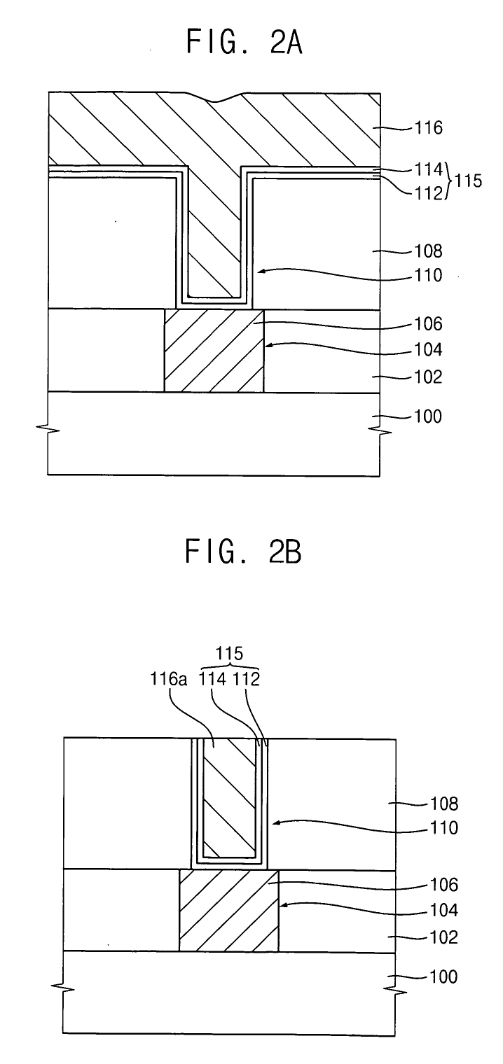

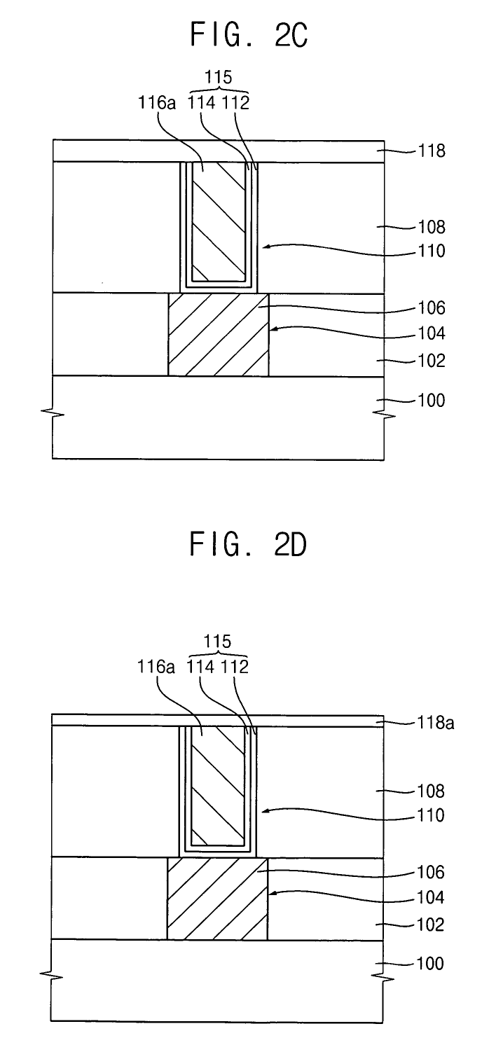

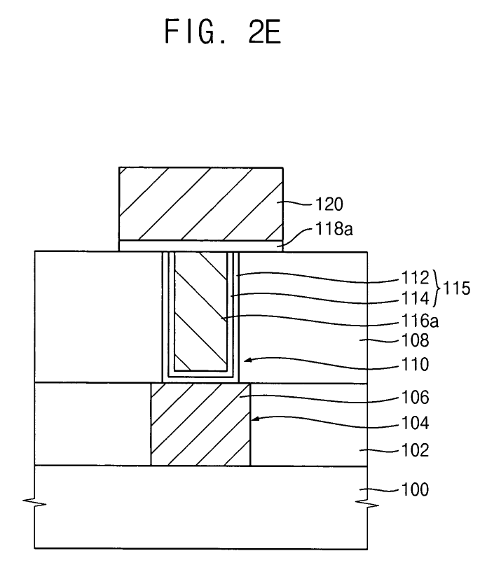

FIGS. 2A to 2E are cross-sectional views illustrating a method of forming a tungsten wiring pattern on a semiconductor device according to a first example embodiment of the invention. As illustrated in FIG. 2A, transistors (not shown) having gate electrodes and source/drain regions are formed on a semiconductor substrate 100 having both an active region and a field region. Then, an insulating layer 102 is formed on the substrate 100 to cover the transistors. The insulting layer 102 may be formed using an oxide such as silicon oxide and may be formed using a chemical vapor deposition (CVD) process, a plasma enhanced chemical vapor deposition (PECVD) process, a high density plasma-chemical vapor deposition (HDP-CVD) process or an atomic layer deposition (ALD) process.

Portions of the insulating layer 102 are then etched using a photolithography process to form first contact holes 104 through which portions of the source/drain regions and/or the gate electrodes are exposed. A polysilicon film is then deposited on the insulating layer 102 and the first contact holes 104 to a thickness sufficient to fill up the first contact holes 104. An upper portion of the polysilicon film is then removed to expose an upper surface of the insulating layer 102 and form a planarized surface. The lower portions of the polysilicon film remaining after the planarization process form SAC pads 106 in each of the first contact holes 104, the SAC pads 106 being in electrical contact with the resource/drain regions and/or the gate electrodes exposed by the first contact holes 104. The upper portion of the polysilicon film may be removed by using a chemical mechanical polishing (CMP) process and/or an etch-back process.

An insulating interlayer 108 is then formed on the insulating layer 102 and the SAC pads 106. The insulating interlayer 108 may be formed using an oxide such as silicon oxide and may be formed using a CVD process, a PECVD process, an HDP-CVD process or an ALD process. Portions of the insulating interlayer 108 are then removed using a photolithography process to form second contact holes 110 that expose portions of the surface of the SAC pads 106.

A titanium film 112 is deposited to a thickness of about 100 Å on the second contact hole 110 and the insulating interlayer 108. A titanium nitride film 114 is then deposited to a thickness of about 100 to about 200 Å on the titanium film 112, thereby forming a composite or stacked barrier layer 115 that includes both the titanium film 112 and the titanium nitride film 114. The titanium film 112 may be formed by, for example, a CVD process using titanium tetrachloride (TiCl₄) or another titanium source gas. The titanium nitride film 114 may also be formed by a CVD process using, for example, TiCl₄, another titanium source gas or a combination of titanium source gases, and ammonia (NH₃), another nitrogen source gas or a combination of nitrogen source gases.

A tungsten film 116 may then be deposited on the barrier layer 115 to a thickness sufficient to fill up the second contact hole 110. The tungsten film 116 may be formed by, for example, a CVD process using a tungsten source gas, for example, hexafluoride (WF₆) gas, in combination with one or more additional reactant gases, for example, silane (SiH₄) and/or hydrogen (H₂) gas. As will be appreciated by those skilled in the art, the deposition of these films may occur in different apparatus, different chambers within a single multi-position apparatus or within a single chamber of a deposition apparatus, depending on the configuration, capacity and capabilities of the available equipment. For example, this example embodiment of the invention may include forming the titanium film 112, the titanium nitride film 114 and the tungsten film 116 in-situ in the single deposition apparatus.

The barrier layer 115 is provided to prevent or suppress diffusion of silicon atoms from the SAC pads 106 into the tungsten film 116 and thereby prevent or suppress generation or occurrence of “spiking” in which the formation of a tungsten/silicon alloy results in “spikes” that disrupt the uniformity of the respective layers in regions in which the tungsten film 116 is in contact with silicon.

When a single layer of titanium is used to form the barrier layer 115 without an overlaying titanium nitride film, the tungsten source gas, for example, WF₆, used in the CVD deposition of the tungsten film 116 can react with the titanium (Ti) and generate an undesirable reaction by-product, e.g., titanium fluoride (TiF₄) and degrade the integrity of the barrier layer. Because titanium nitride exhibits greater resistance to the formation of such undesirable reaction by-products, a barrier layer 115 exhibiting a stacked structure incorporating an inner or lower titanium film 112 coupled with an outer or upper titanium nitride film 114 will improve the quality and performance of the barrier layer 115. Additionally, the titanium nitride film 114 tends to improve the adhesion strength between tungsten and the insulating interlayer.

As illustrated in FIG. 2B, an upper portion of the tungsten film 116 is then removed to expose an upper surface of the insulating interlayer 108, thereby forming a tungsten contact plug 116a in the second contact hole 110 and providing a planarized surface suitable for subsequent processing. The upper portion of the tungsten film 116 may be removed using a chemical mechanical polishing (CMP) process and/or an etch-back process.

As illustrated in FIG. 2C, a layer of titanium nitride is then deposited on the exposed surfaces of the insulating interlayer 108 and the tungsten contact plug 116a to thereby form an adhesion layer 118. The adhesion layer 118 may be formed by a CVD process using, for example, TiCl₄ and NH₃ as source gases. As will be appreciated, other titanium and nitrogen source gases may be utilized and may provide an alternative to or may be combined with the TiCl₄ and NH₃ source gases.

The adhesion layer 118 is provided for increasing the adhesive strength between the upper surface of the insulating interlayer 108 and a tungsten wiring pattern that will be formed in a subsequent process. In this first example embodiment of the invention, the adhesion layer 118 may be formed to a sufficient thickness, e.g., about 500 Å, to provide a sufficient margin during a subsequent etch-back process while still tending to improve adhesion between the tungsten film and the underlying insulating materials. For example, in this example embodiment of the invention, the etch-back process may be conducted under conditions and for a duration sufficient to provide an adhesion layer 118 having a thickness of not more than about 300 Å. An adhesion layer 118 of, for example, titanium nitride, will tend to exhibit a uniformly rough surface corresponding in large part to the method used to form the adhesion layer, for example, with a CVD process utilizing a TiCl₄ source gas.

As illustrated in FIG. 2D, an upper portion of the adhesion layer 118 is removed using an etch-back process. During the etch-back process, certain of the surface irregularities will be removed from the surface of the adhesion layer 118, thereby increasing the smoothness of the surface of the adhesion layer.

The etch-back process may be carried out by a time etching method using chlorine (Cl₂) based etching gas. As used herein, the reference number 118a indicates the post etch-back adhesion layer, i.e., the remaining lower portion of the adhesion layer that exhibits decreased RMS surface roughness.

As illustrated in FIG. 2E, a tungsten film is then deposited on the adhesion layer 118a exhibiting decreased RMS surface roughness. The tungsten film may, for example, be formed by a CVD process using WF₆ gas and SiH₄ and/or H₂ gas. As the tungsten film is being deposited on the adhesion layer 118a exhibiting decreased RMS surface roughness, enlarged tungsten nuclei are created on the smooth surface of the adhesion layer 118a. The metal grains then grow from each of these enlarged nuclei to produce a tungsten film exhibiting enlarged grains on the adhesion layer 118a.

A photoresist pattern may then be formed on the tungsten film using a conventional photolithography process. Using the photoresist pattern as an etch mask, portions of the tungsten film and the adhesion layer 118a may then be etched to form a tungsten wiring pattern 120. The tungsten wiring pattern 120 may, for example, define a bit line and that is electrically connected to the transistor (not shown) through both the tungsten contact plug 116a and the SAC pad 106.

According to this example embodiment, after forming the tungsten contact plug 116a, the adhesion layer 118a is formed and partially etched back so as to provide a smoother deposition surface for the tungsten layer. The tungsten wiring pattern 120 may be utilized as a bit line in a semiconductor memory device. The tungsten film, and the tungsten wiring pattern 120 etched from the tungsten film, exhibit increased grain size and reduced sheet resistance. These improvements are attributed to forming the tungsten film on the surface of the adhesion layer 118 that had previously been processed to improve the film smoothness (or, put another way, to decrease the RMS roughness of the film).

Although not limited to any particular products, it is anticipated that the method of forming the tungsten wiring pattern according to the example embodiment of the invention described above may be useful in manufacturing a variety of semiconductor devices. In particular, it is anticipated that methods of manufacturing tungsten wiring patterns for semiconductor devices incorporating or requiring a high degree of integration according to the example embodiments of the invention will be useful for manufacturing DRAM memory devices, SRAM memory devices and/or non-volatile memory devices. As will be appreciated to those skilled in the art, the methods according to the example embodiments of the invention may be applied to various other types of semiconductor devices.

### Second Example Embodiment

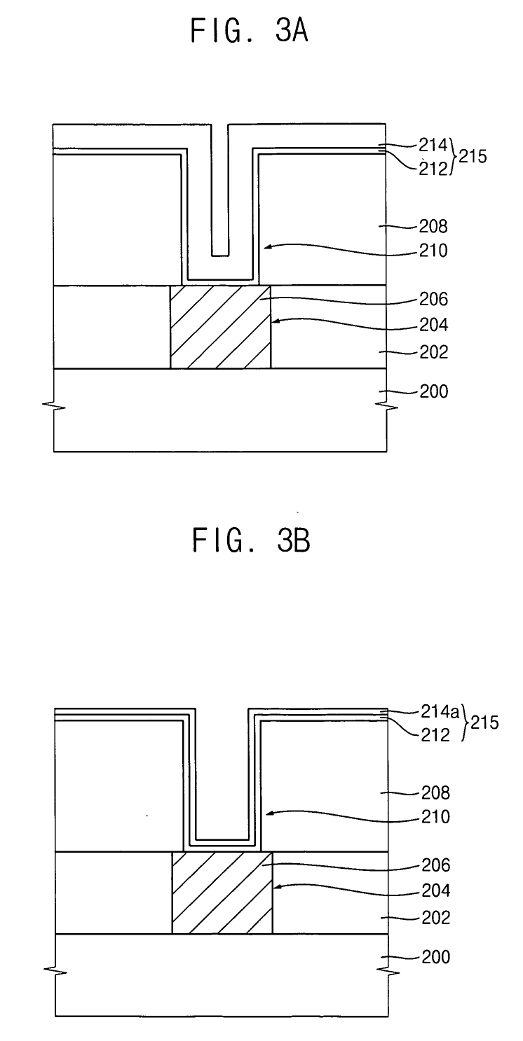

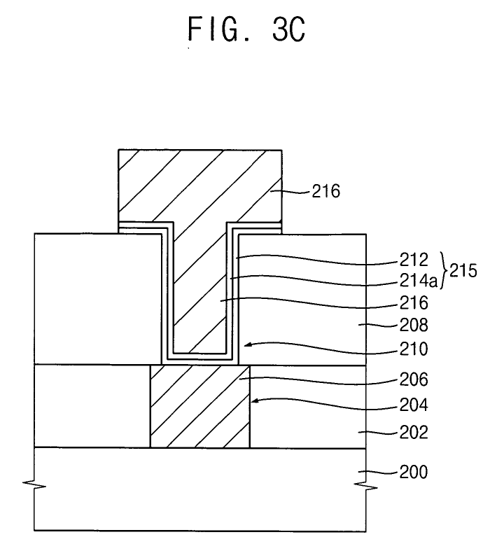

FIGS. 3A to 3C are cross-sectional views illustrating a method of forming a tungsten wiring in a semiconductor device according to a second example embodiment of the invention. This example embodiment illustrates an instance in which a tungsten contact plug and a tungsten wiring pattern incorporate an integrally formed structure.

As illustrated in FIG. 3A, transistors (not shown) having gate electrodes and source/drain regions are formed on a semiconductor substrate 200 which includes both an active region and a field region. An insulating layer 202 is then formed on the substrate 200 to cover the transistors. The insulting layer 202 may be formed using an oxide such as silicon oxide and may be formed using a chemical vapor deposition (CVD) process, a plasma enhanced chemical vapor deposition (PECVD) process, a high density plasma-chemical vapor deposition (HDP-CVD) process or an atomic layer deposition (ALD) process.

Portions of the insulating layer 202 may then be patterned and etched away using a conventional photolithography process to form first contact holes 204 that expose portions of the gate electrodes and/or the source/drain regions of the underlying transistors. A polysilicon film is then deposited on the insulating layer 102 to a thickness sufficient to fill the first contact holes 204. The upper portion of the polysilicon film is then removed to expose an upper surface of the insulating layer 202 with the remaining portion of the polysilicon film forming SAC pads 206 in each of the first contact holes 204 that are in electrical contact with the source/drain regions and/or the gate electrode. The upper portion of the polysilicon film may be removed by using a CMP process and/or an etch-back process.

An insulating interlayer 208 is then formed on the exposed surfaces of the insulating layer 202 and the SAC pads 206. The insulating interlayer 208 may be formed using an oxide such as silicon oxide and may be formed by a CVD process, a PECVD process, an HDP-CVD process or an ALD process. The insulating interlayer 208 may then be patterned and etched using a conventional photolithography process to form second contact holes 210 that expose an upper surface of the SAC pad 206 through which electrical contact may be made to the source/drain regions and/or gate electrodes of the underlying transistor(s).

A titanium film 212 is then deposited to a thickness of about 100 Å on the second contact hole 210 and the insulating interlayer 208. A titanium nitride film 214 is then deposited to a thickness of at least 300 Å on the titanium film 112, thereby forming a composite barrier layer 215 that includes the titanium film 212 and the titanium nitride film 214. The titanium film 212 may be formed using a CVD process with titanium tetrachloride (TiCl₄) gas or another suitable titanium source gas while the titanium nitride film 214 may be formed using a CVD process using, for example, TiCl₄ and ammonia (NH₃) gases as source gases.

As formed, the titanium nitride film 214 will exhibit a uniformly rough surface depending on, for example, the method and equipment used to form such a film. The titanium layer may, for example, be formed using a CVD process with a TiCl₄ gas, but those skilled in the art will appreciate that it is expected that other source gases may be utilized in forming the titanium layer. In the example embodiment of the invention here described, the titanium nitride film 214 may be deposited to a sufficiently thick thickness, e.g., about 300 to about 500 Å, to provide both a satisfactory margin for the etch-back process and enough of the barrier layer will remain to suppress or prevent migration of the silicon into the primary conductive metal, e.g., tungsten.

As illustrated in FIG. 3B, the upper film of the barrier layer 215, i.e., titanium nitride film 214, is then partially removed using an etch-back process to remove rougher portions of the surface of the titanium nitride film. As a result, the post etch-back titanium nitride film 214a exhibits a surface roughness less than that of the titanium nitride film as deposited.

In the present embodiment of the invention, the etch-back process may be carried out so that the remaining portion of the titanium nitride film 214a has a thickness of about 100 to about 200 Å. That is, the titanium nitride film 214 is partially etched back so that the remaining portion of the tungsten nitride film 214a has a thickness sufficient to serve as the barrier layer while still exhibiting a decreased surface roughness.

The etch-back process may be carried out by a time etching method using chlorine (Cl₂) based etching gas. Here, as noted above, reference number 214a indicates the titanium nitride film in which the surface roughness has been reduced by a partial etch-back process.

As illustrated in FIG. 3C, a tungsten film is then deposited to a thickness sufficient to fill up the second contact hole 210 on the titanium nitride film 214a having the smooth surface. The tungsten film may be formed by a CVD process using, for example, a combination of tungsten hexafluoride (WF₆) gas, silane (SiH₄) and/or hydrogen (H₂) gas as the reactant gases.

When the tungsten film is formed on the surface of the titanium nitride film 214a that exhibits decreased surface roughness, the resulting tungsten nuclei tend to be enlarged. Consequently, the metal grains growing from these nuclei are also enlarged to produce a tungsten film having both enlarged metal grains and reduced sheet resistance relative to a tungsten film formed on an “as deposited” titanium nitride layer. A photoresist pattern may then be formed on the tungsten film using a suitable conventional photolithographic process. Using the photoresist pattern (not shown) as an etch mask, portions of the tungsten film and the barrier layer 215 may be removed to form a tungsten wiring pattern 216 that may, for example, be utilized as a bit line that is electrically connected to the underlying transistor (not shown) through SAC pad 206.

According to the second example embodiment, after forming the barrier layer 215, which typically includes both a titanium film 212 and the titanium nitride film 214, the titanium nitride film is partially etched back in order to decrease the average surface roughness. The tungsten wiring pattern 216 can serve as a bit line in which the sheet resistance has been reduced by increasing the average grain size of the tungsten deposited on the smoothed surface 214a of the barrier layer 215.

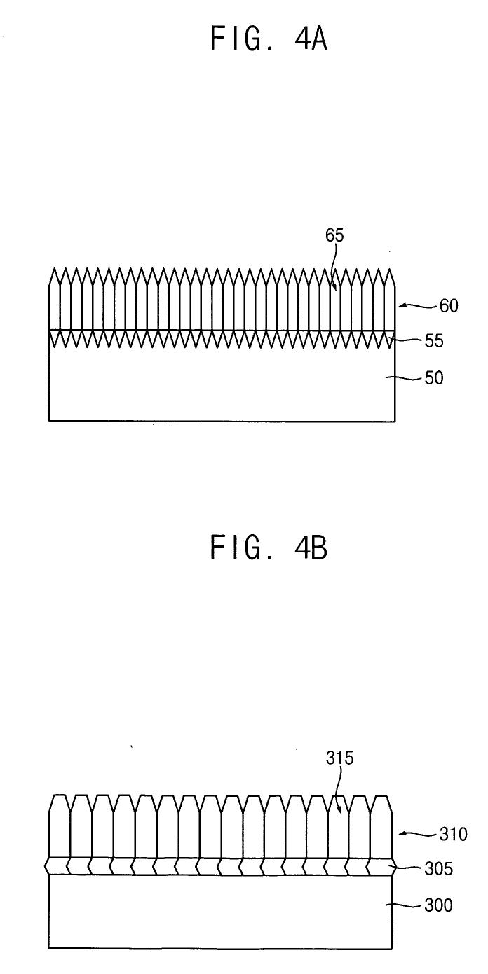

As will be appreciated by one skilled in the art, the present method of forming the tungsten wiring may be also incorporated in methods for manufacturing DRAM memory devices, SRAM memory devices and certain non-volatile memory devices. FIGS. 4A and 4B are cross-sectional views illustrating the relative grain morphologies of a titanium nitride film and a tungsten film formed according to the convention method and the invention, respectively.

As illustrated in FIG. 4A, a titanium nitride film 50 deposited using a conventional CVD process may be formed by a chemical reaction using TiCl₄ gas as a source gas and which may be represented by formula (I):
TiCl₄+NH₃→TiN+HCl (1)

Because the titanium nitride film 50 formed by the above chemical reaction has a uniformly rough surface, a number of dangling bonds exists on the surface of the titanium nitride film 50. Accordingly, it is quite probable that atoms of a film deposited thereon will combine with the dangling bonds to create nuclei, thereby increasing nucleation sites.

In other words, when a tungsten film 60 is deposited using a CVD process on the titanium nitride film 50, tungsten nuclei 55 are created of uniformly small size on the rough surface having the numerous nucleation sites. Each nucleus 55 forms a grain 65 while growing. The grain formed from one nucleus continues to grow until the grain collides with a grain growing and advancing from an adjacent nucleus. Because the grains 65 will be relatively small and uniform when a tungsten film is formed using tungsten nuclei 55 having uniformly small size, the resulting tungsten film 60 will comprise grains 65 that are correspondingly small and uniform. The tungsten film 60 having the grains of small size may exhibit a sheet resistivity of about 17.2 Ω-cm.

On the contrary, according to the example embodiments of the invention, the grain size of a tungsten film 310 can be increased by utilizing the relationship between the tungsten film grain size and the surface state of the underlying film, thereby decreasing resistivity.

Particularly, as shown in FIG. 4B, a titanium nitride film 300 is deposited by a CVD process using TiCl₄ gas and then, partially etched back. By doing so, rough portions of the surface of the titanium nitride film 300 are removed to make its surface smooth such that the RMS roughness is no more than about 10 Å. The smooth surface has a small number of dangling bonds to which atoms of a film to be deposited thereon are combined, thereby decreasing the nucleation sites.

Accordingly, when the tungsten film 310 is deposited by a CVD process on the titanium nitride film 300 having the smooth surface, the tungsten nuclei 305 of large size are created on the smooth surface of the titanium nitride film 300, and these large nuclei 305 grow into grains 315 of large size because the adjacent nuclei 305 are of small number.

When an ordinary film has the grains of large size, the grain boundaries of the film are decreased. This means that the number of current barrier is decreased to reduce the resistivity of the film. In the invention, the tungsten film 310 having the grains 315 of large size can be obtained at the same film thickness as compared with the tungsten film formed by the conventional method. As a result, the tungsten film of corresponding thickness can be formed while reducing the sheet resistivity to about 13.6 Ω-cm, a reduction of about 21% as compared with the conventional tungsten film.

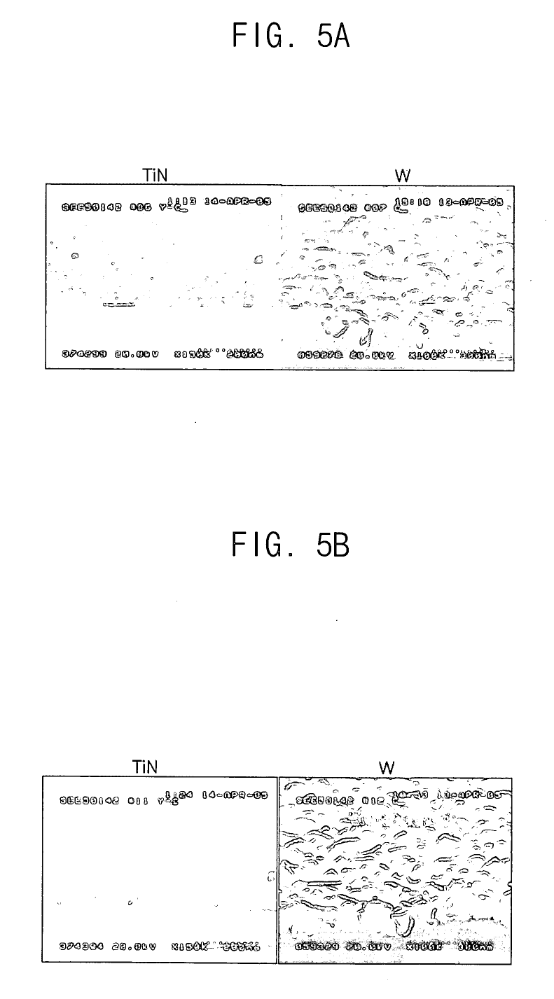

FIGS. 5A and 5B are pictures showing the surfaces of the titanium nitride film and tungsten film photographed by scanning electron microscope (SEM) according to the convention method and the invention, respectively. FIG. 5A shows surfaces of a titanium nitride (TiN) film and tungsten (W) film formed on the TiN film according to the conventional method. As shown in FIG. 5A, the titanium nitride film has a uniformly rough surface and the grain sizes exhibited in the tungsten film deposited on the titanium nitride film are relatively small and uniform. FIG. 5B, on the other hand, shows surfaces of a titanium nitride (TiN) film and a tungsten (W) film formed on the TiN film using a method according to an example embodiment of the invention. As shown in FIG. 5B, the titanium nitride film exhibits reduced surface roughness, i.e., has a relatively smooth surface, and thus the grain sizes of the tungsten film deposited on the titanium nitride film are correspondingly larger than those of the tungsten film formed by the conventional method.

According to the example embodiments of the invention as described above, the surface of the underlying film such as an adhesion layer or a barrier layer formed under the tungsten film is smoothed by the etch-back process to provide a smooth surface on which the tungsten film is subsequently deposited. The grain sizes of the tungsten film deposited on the smooth surface of the underlying film become larger, so that the resistivity of the tungsten film can be reduced.

Although example embodiments of the invention have been described, it is understood that the invention should not be limited to these some embodiments but various changes and modifications can be made by one skilled in the art within the spirit and scope of the invention as hereinafter claimed.

What is claimed is:

1. A method of forming a tungsten film, comprising:
forming a first film having an initial surface roughness on a semiconductor substrate;
removing an upper portion of the first film to form a deposition surface having a reduced surface roughness relative to the initial surface roughness; and
forming a tungsten film on the deposition surface.

2. The method according to claim 1, wherein the deposition surface exhibits a RMS roughness of no more than about 10 Å.

3. A method of forming a metallic wiring pattern in a semiconductor device comprising:
forming an adhesion layer having an initial surface roughness on a semiconductor substrate;
reducing the initial surface roughness of the adhesion layer to form a deposition surface on the adhesion layer;
forming a layer of a metallic material on the deposition surface; and
removing portions of the metallic material and the adhesion layer to form the metallic wiring pattern.

4. The method of forming a metallic wiring pattern according to claim 3, further comprising:
forming an insulating interlayer on the semiconductor substrate;
forming a contact hole in the insulating interlayer to expose a portion of the semiconductor substrate;
forming a barrier layer in the contact hole;
forming a conductive contact plug on the barrier layer in the contact hole; and
forming the adhesion layer on the insulating interlayer and an upper surface of the conductive contact plug, whereby electrical contact is formed between the metallic wiring pattern and the semiconductor substrate.

5. The method according to claim 4, wherein the adhesion layer comprises titanium nitride.

6. The method according to claim 4, wherein the metallic material comprises tungsten.

7. The method according to claim 4, wherein the metallic material consists essentially of tungsten.

8. The method according to claim 4, wherein the deposition surface has a RMS roughness of no more than about 10 Å.

9. The method according to claim 4, wherein forming the conductive contact plug on the barrier layer in the contact hole includes:
forming the barrier layer in the contact hole and an upper surface of the insulating interlayer;
forming a metal film on the barrier layer, a thickness of the metal film being sufficient to fill the contact hole; and
removing an upper portion of the metal film and the barrier layer to expose the upper surface of the insulating interlayer.

10. The method according to claim 9, wherein:
the barrier layer includes a first layer of titanium formed on the insulating interlayer and a second layer of titanium nitride formed on the first layer; and
the metal film includes a major portion of tungsten.

11. A method of forming a conductive wiring pattern in a semiconductor device, comprising:
forming an insulating interlayer on a semiconductor substrate;
forming a contact hole in the insulating interlayer to expose a portion of the semiconductor substrate;
forming a barrier layer having an initial RMS surface roughness on the contact hole and the insulating interlayer;
removing an upper portion of the barrier layer to form a deposition surface having a final RMS surface roughness less than that of the initial RMS surface roughness;
forming a metal film on the deposition surface; and
removing portions of the metal film and the barrier layer to form a metal wiring pattern.

12. The method according to claim 11, wherein the metal film comprises tungsten.

13. The method according to claim 12, wherein forming the barrier layer includes:
forming a titanium film; and
forming a titanium nitride film on the titanium film.

14. The method according to claim 13, wherein removing the upper portion of the barrier layer includes etching back the titanium nitride layer to leave a sufficient thickness of the titanium nitride layer to protect the titanium layer.

15. The method according to claim 14, wherein the thickness of the titanium nitride layer is sufficient to protect the titanium layer from damage during the formation of the metal film on the deposition surface.

16. The method according to claim 15, wherein the thickness of the titanium nitride layer is sufficient to protect the titanium layer from damage by WF₆ during the formation of a tungsten film on the deposition surface.

17. The method according to claim 11, wherein removing the upper portion of the barrier layer includes etching back the barrier layer

18. The method according to claim 11, wherein the final RMS surface roughness is no more than about 10 Å.

19. The method according to claim 11, wherein a ratio of the initial RMS surface roughness and the final RMS surface roughness is at least 2:1.

20. The method according to claim 11, wherein a ratio of the initial RMS surface roughness and the final RMS surface roughness is at least 4:1.
